(19) United States
(12) Patent Application Publication
(10) Pub. No.: US 2019/0374911 A1
(43) Pub. Date: Dec. 12, 2019

(54) CLEANING APPARATUS FOR SEMICONDUCTOR SUBSTRATES AND CLEANING METHOD FOR SEMICONDUCTOR SUBSTRATES

(71) Applicant: KURITA WATER INDUSTRIES LTD., TOKYO (JP)

(72) Inventor: Yu FUJIMURA, Tokyo (JP)

(73) Assignee: KURITA WATER INDUSTRIES LTD., TOKYO (JP)

(21) Appl. No.: 16/484,120

(22) PCT Filed: Sep. 12, 2017
(86) PCT No.: PCT/JP2017/032789

§ 371 Date: Aug. 7, 2019

(30) Foreign Application Priority Data
Feb. 7, 2017 (JP) 2017-020428

(51) Int. Cl. B01F 3/22; C02F 1/20; C02F 1/68; B01F 3/04; B01F 3/20; H01L 21/67; H01L 21/02

(52) U.S. Cl. CPC B01F 3/2215; C02F 1/20; C02F 1/68; C02F 2103/346; B01F 3/2021; H01L 21/67057; H01L 21/02057; B01F 3/04241

(57) ABSTRACT

A cleaning apparatus (10) for a semiconductor substrate that cleans a semiconductor substrate by using ozone water, including cooling means (3) for cooling ozone water (W2) of 20° C. or more to a predetermined temperature, and cleaning means (4) for cleaning a substrate by using ozone water (W3) cooled by the cooling means (3). The cleaning means (4) has a cleaning tank (41) for cleaning the substrate by immersing the substrate in the ozone water (W3) cooled by the cooling means (3). According to a cleaning method using the semiconductor substrate cleaning apparatus (10), by immersing a semiconductor substrate in ozone water, organic substances, such as resist, and metal foreign materials remaining on the substrate surface are cleaned and removed, and the loss of substrate material in a cleaning step can be reduced.

### TECHNICAL FIELD

The present invention relates to a cleaning apparatus and a cleaning method for a semiconductor substrate, and particularly to a cleaning apparatus and a cleaning method for a semiconductor substrate by immersing the semiconductor substrate in ozone water.

### BACKGROUND ART

In manufacturing of a semiconductor device, contaminants of organic substances, such as resist, and metal foreign materials generated in a manufacturing process may cause deterioration or the like in electrical characteristics of semiconductors when the contaminants adhere to or remain on the surface of a semiconductor substrate, which greatly affects the quality of the semiconductor device. Accordingly, cleaning of the semiconductor substrate is an extremely important issue in the manufacturing of the semiconductor device.

A wet cleaning method using liquid as a medium and a dry cleaning method performed by a dry process are known as a cleaning method for semiconductor substrates. The wet cleaning method includes an immersion type for immersing a substrate in liquid and a single wafer type for jetting liquid to a substrate. Conventionally, in the manufacturing of semiconductor devices, substrates have been cleaned on the basis of an RCA cleaning method which is an immersion type wet cleaning method. After the RCA cleaning, the substrate is rinsed with ultrapure water after an oxide film formed on the surface thereof is removed with hydrofluoric acid.

The RCA cleaning method is a method for removing organic substances and metal foreign materials adhering to the surface of a substrate by using a large amount of high-concentration chemical solution. Accordingly, the RCA cleaning method separately requires facilities for treating wastewater of the high-concentration chemical solution after the cleaning, toxic gas and the like generated from a cleaning apparatus, and thus under the present condition, the RCA cleaning method is used while having such a problem as increase in processing cost and environmental impacts.

As a countermeasure to the foregoing problem, in recent years, a cleaning method for cleaning a semiconductor substrate in ozone water by immersing the semiconductor substrate, for example, as disclosed in Patent Documents 1 and 2, has been proposed. In a substrate processing method disclosed in Patent Document 2, ozone water obtained by dissolving ozone gas at a high concentration in pure water manufactured at a relatively low temperature is heated up to a temperature in a range from about 20° C. to about 40° C., whereby the surface of the substrate is treated while high oxidizing power is maintained to enhance a cleaning effect. High-concentration ozone water has a smaller amount of metal impurities than conventional high-concentration chemical solution, and changes to harmless substances over time, so the high-concentration ozone water has an advantage that environmental impacts is low.

By the way, with the recent progress of high integration of semiconductor devices and miniaturization of circuit patterns, the requirement for the quality of substrate surfaces is becoming more and more severe, so that further improvement of the cleaning performance is required. Accompanying this requirement, it is required to reduce the loss of substrate material in a cleaning step from the viewpoint of reducing the environmental impacts. The above-mentioned cleaning method can perform the removal of organic substances and metal foreign materials on the substrate surfaces. However, since the ozone concentration in ozone water is very high, an oxide film having a large thickness is formed on the substrate surface, which causes a disadvantage that the loss of substrate material increases.

### PRIOR ART DOCUMENT

### Patent Document

Patent Document 1: Japanese Patent No. 4054374

Patent Document 2: Japanese Patent No. 3691985

### SUMMARY OF THE INVENTION

### Problems to be Solved by the Invention

The present invention has been made in consideration of such circumstances and an object of the present invention is to provide a cleaning apparatus and a cleaning method for a semiconductor substrate that can clean and remove organic substances, such as resist, and metal foreign materials remaining on the surface of the substrate by immersing the semiconductor substrate in ozone water, and reduce the loss of substrate material in a cleaning step.

### Means for Solving the Problems

To achieve the above object, first, the present invention provides a substrate cleaning apparatus for cleaning a substrate by using ozone water, comprising: cooling means for cooling ozone water of 20° C. or more to a predetermined temperature; and cleaning means for cleaning a substrate with ozone water cooled by the cooling means (Invention 1).

According to the above invention (Invention 1), since the activity of the dissolved ozone is reduced by using the low-temperature ozone water cooled to the predetermined temperature for cleaning of the substrate, formation of an oxide film on the substrate surface can be suppressed, and thus it is possible to reduce the loss of substrate material.

In the above invention (Invention 1), it is preferable that the cleaning means includes a cleaning tank for cleaning the substrate by immersing the substrate in the ozone water cooled by the cooling means (Invention 2).

According to the above invention (Invention 2), since the entire substrate can be immersed in the cooled ozone water, a problem such as occurrence of static electricity does not occur, and the cleaning can be efficiently performed.

In the above inventions (Invention 1, 2), it is preferable that the cooling means includes a chiller capable of cooling ozone water to 0° C. or more and less than 20° C. (Invention 3).

According to the above invention (Invention 3), since the temperature of the ozone water to be supplied to the cleaning means can be controlled to 0° C. or more and less than 20° C., it is possible to perform the cleaning stably with the cooled ozone water.

In the above Inventions (Inventions 1 to 3), it is preferable that the substrate cleaning apparatus further comprises ozone water generating means for generating ozone water to be supplied to the cooling means, and the ozone water generating means includes an ozone generating device for generating ozone, and a dissolving membrane module for dissolving ozone generated by the ozone generating device in ultrapure water (Invention 4).

According to the above invention (Invention 4), by using the dissolving membrane module, ozone having a relatively small dissolution rate in water can be efficiently dissolved in degassed ultrapure water, so high concentration ozone water can be generated.

In the above inventions (Inventions 1 to 4), it is preferable that the substrate cleaning apparatus further comprises degassing means for degassing ultrapure water to be supplied to the dissolving membrane module, and the degassing means includes a degassing membrane module and a vacuum pump (Invention 5).

According to the above invention (Invention 5), by using the vacuum pump to set the discharge port side of the degassing membrane module to a vacuum state, dissolved gas causing oxidation of ultrapure water and breeding of bacteria can be efficiently discharged to the outside of the degassing membrane module, so that it is possible to efficiently obtain degassed ultrapure water.

Secondly, the present invention provides a substrate cleaning method for cleaning a substrate by using ozone water comprising: a cooling step of cooling ozone water of 20° C. or more to a predetermined temperature; and a cleaning step of cleaning the substrate with the ozone water cooled in the cooling step (Invention 6).

### Effect of the Invention

According to the cleaning apparatus and the cleaning method of the present invention, the activity of dissolved ozone is reduced by using low-temperature ozone water cooled to a predetermined temperature for cleaning of a substrate, so that formation of an oxide film on the surface of the substrate is suppressed, and thus it is possible to reduce the loss of substrate material.

### BRIEF DESCRIPTION OF DRAWING

FIG. 1 is an explanatory diagram illustrating a cleaning apparatus for a semiconductor substrate according to an embodiment of the present invention.

### DESCRIPTION OF THE EMBODIMENTS

Embodiments of a cleaning apparatus for a semiconductor substrate and a cleaning method for a semiconductor substrate according to the present invention will be described below appropriately with reference to the drawing. The embodiments described below are for the purpose of facilitating the understanding of the present invention, and do not limit the present invention at all.

[Clearing Apparatus for Semiconductor Substrate]

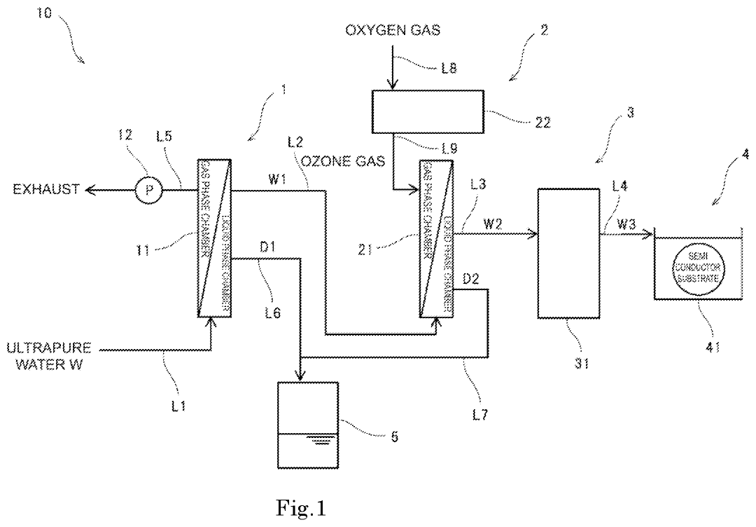

FIG. 1 is an explanatory diagram illustrating a cleaning apparatus 10 for a semiconductor substrate according to an embodiment of the present invention. The cleaning apparatus 10 illustrated in FIG. 1 mainly includes degassing means 1, ozone water generating means 2, cooling means 3, and cleaning means 4. The degassing means 1 is adapted to degas ultrapure water W (18.2 MΩ<), and includes a degassing membrane module 11 and a vacuum pump 12. The ozone water generating means 2 is adapted to generate ozone water W2, and includes an ozone generating device 22 for generating ozone gas, and a dissolving membrane module 21 for dissolving ozone gas generated by the ozone generating device 22 in ultrapure water W1 which has been subjected to a degassing treatment. The cooling means 3 is adapted to cool ozone water W2, and includes a chiller 31 capable of cooling the ozone water W2 to 0° C. or more and less than 20° C. The cleaning means 4 is adapted to clean a semiconductor substrate, and includes a cleaning tank 41 for cleaning the semiconductor substrate by immersing the semiconductor substrate in ozone water W3 cooled by the chiller 31.

The cleaning apparatus 10 for a semiconductor substrate is provided with a supply pipe L1 for supplying ultrapure water W from a raw water tank (not illustrated) to the degassing membrane module 11, a supply pipe L2 for connecting the degassing membrane module 11 and the dissolving membrane module 21, a supply pipe L3 for connecting the dissolving membrane module 21 and the chiller 31, and a supply pipe L4 connecting the chiller 31 and the cleaning tank 41. The vacuum pump 12 is connected to the degassing membrane module 11 via a vacuum pipe L5. Waste water pipes L6 and L7 for discharging drain water D1 and D2 are connected to the degassing membrane module 11 and the dissolving membrane module 21 respectively, and the waste water pipes L6 and L7 are connected to a drain tank 5. An ozone gas supply pipe L9 for supplying ozone gas generated by the ozone generating device 22 is connected to the dissolving membrane module 21, and an oxygen gas supply pipe L8 for supplying oxygen gas is connected to the ozone generating device 22.

(Degassing Means)

The degassing means 1 is adapted to remove dissolved oxygen, dissolved carbon dioxide and the like in the ultrapure water W, and includes the degassing membrane module 11 and the vacuum pump 12. The inside of the degassing membrane module 11 is compartmented into a liquid phase chamber and a gas phase chamber by a degassing membrane, ultrapure water W is introduced from an introduction port side of the liquid phase chamber, and degassed ultrapure water W1 is discharged from a discharge port side. No limitation is particularly imposed on the degassing membrane of the degassing membrane module 11 insofar as the degassing membrane does not permeate water therethrough, but permeates gas dissolved in water therethrough, and for example, a polymer membrane such as polypropylene, polydimethylsiloxane, polycarbonate-polydimethylsiloxane block copolymer, polyvinylphenol-polydimethylsiloxane-polysulfone block copolymer, poly(4-methylpentene-1), poly(2,6-dimethylphenylene oxide) or polytetrafluoroethylene, or the like is applicable. The vacuum pump 12 is connected to the gas phase chamber of the degassing membrane module 11 through the vacuum pipe L5. No imitation is particularly imposed on the vacuum pump 12, and for example, a pump capable of sucking water vapor such as a water-sealed vacuum pump or a scroll pump having a water vapor removal function is applicable. By reducing the pressure on the gas phase chamber side of the degassing membrane module 11 with the vacuum pump 12, it is possible to efficiently exhaust dissolved gas causing oxidation of ultrapure water and breeding of bacteria to the outside of the degassing membrane module 11, so that the degassed ultrapure water W1 can be efficiently obtained.

(Ozone Water Generating Means)

The ozone water generating means 2 is adapted to generate ozone water W2 by dissolving ozone gas in degassed ultrapure water W1, and includes the ozone generating device 22 for generating ozone gas based on oxygen gas, and the dissolving membrane module 21 for dissolving the ozone gas generated by the ozone generating device 22 in the degassed ultrapure water W1. No limitation is particularly imposed on the ozone generating device 22, and a known silent discharge type, an ultraviolet lamp type, a water electrolysis type or the like is applicable. The inside of the dissolving membrane module 21 is compartmented into a liquid phase chamber and a gas phase chamber by a dissolving membrane, degassed ultrapure water W1 is introduced from an introduction port side of the liquid phase chamber, and generated ozone water W2 is discharged from a discharge port side. No limitation is particularly imposed on the dissolving membrane of the dissolving membrane module 21 insofar as the dissolving membrane does not permeate water therethrough, but permeates gas dissolved in water therethrough. For example, a polymer membrane such as polypropylene, polydimethylsiloxane, polycarbonate-polydimethylsiloxane block copolymer, polyvinylphenol-polydimethylsiloxane-polysulfone block copolymer, poly(4-methylpentene-1), poly(2,6-dimethylphenylene oxide) or polytetrafluoroethylene, or the like is applicable. By using the dissolving membrane module 21, ozone having a relatively small dissolution rate in water can be efficiently dissolved in the degassed ultrapure water W1, so that high-concentration ozone water W2 can be generated.

Note that since heated ultrapure water (warm ultrapure water) is generally used to dissolve ozone gas at a high concentration for generation of high-concentration ozone water, the high-concentration ozone water W2 described above usually has a water temperature of 20° C. or more. In the cleaning apparatus 10 for a semiconductor substrate, the supply pipe L2 may be provided with a heating device (not illustrated) for controlling the temperature of the degassed ultrapure water W1 to be supplied to the dissolving membrane module 21.

(Cooling Means)

The cooling means 3 is adapted to cool the ozone water W2, and includes the chiller 31 capable of cooling the ozone water W2 to 0° C. or more and less than 20° C. No limitation is particularly imposed on the chiller 31 insofar as the chiller 31 is capable of cooling the ozone water W2 to 0° C. or more and less than 20° C., and a known cooling device can be applied. The ozone water W3 whose temperature is controlled to 0° C. or more and less than 20° C. is reduced in the activity of dissolved ozone, which makes it possible to suppress formation of an oxide film on the surface of the semiconductor substrate in the cleaning means 4 in a subsequent stage, so that the loss of the substrate material can be reduced.

Note that the cooling means 3 may include a chiller unit having plural chillers 31 connected side by side, and this chiller unit may be configured to be capable of switching the operating states of the plural chillers 31 according to the degree of deterioration of the cooling function of each chiller 31. The cooling means 3 has such a configuration, whereby a chiller 31 to be used can be selected by switching the operating states of the plural chillers 31. Therefore, even when there is a chiller 31 whose cooling function deteriorates due to, for example, occurrence of microorganisms or the like, the operation of the entire chiller unit can be continued without being stopped, and the production efficiency of the cooled ozone water W3 is enhanced.

(Cleaning Means)

The cleaning means 4 is adapted to clean the semiconductor substrate with the cooled ozone water W3, and includes the cleaning tank 41 for cleaning the semiconductor substrate by immersing the semiconductor substrate in the ozone water W3 cooled to 0° C. or more and less than 20° C. No limitation is particularly imposed on the cleaning tank 41 insofar as the whole semiconductor substrate to be cleaned can be immersed, and existing ones can be applied. By using the cleaning tank 41, the entire substrate can be immersed in the cooled ozone water W3. Therefore, a problem such as occurrence of static electricity does not occur, and efficient cleaning can be performed. Further, since the ozone water W3 whose temperature is controlled to 0° C. or more and less than 20° C. is reduced in the activity of dissolved ozone, the formation of the oxide film on the surface of the semiconductor substrate can be suppressed, so that the loss of the semiconductor substrate material can be reduced and the semiconductor substrate can be stably cleaned.

[Cleaning Method for Semiconductor Substrate]

Next, a cleaning method using the cleaning apparatus 10 for a semiconductor substrate according to the embodiment as described above will be described in detail with reference to FIG. 1.

(Degassing Step)

In a degassing step, first, the ultrapure water W (18.2 MΩ<) is introduced from the supply pipe L1 into the liquid phase chamber of the degassing membrane module 11. At this time, the gas phase chamber side of the degassing membrane module 11 is reduced in pressure by the vacuum pump 12, so that dissolved oxygen and dissolved carbon dioxide that cause oxidation and breeding of bacteria in the ultrapure water W are exhausted to the outside of the degassing membrane module 11. As a result, degassed ultrapure water W1 is obtained. The degassed ultrapure water W1 is passed through the supply pipe L2 and then supplied to the dissolving membrane module 21 in a subsequent stage. Note that drain water D1 of the degassing membrane module 11 is passed through the waste water pipe L6 and then stored in the drain tank 5.

(Ozone Water Generating Step)

In an ozone water generating step, oxygen gas is first introduced from the oxygen gas supply pipe L8 into the ozone generating device 22, and ozone gas is generated based on the oxygen gas. The generated ozone gas is introduced from the ozone gas supply pipe L9 into the gas phase chamber of the dissolving membrane module 21, and the degassed ultrapure water W1 is supplied from the supply pipe L2 into the liquid phase chamber. By dissolving the ozone gas in the degassed ultrapure water W1 inside the dissolving membrane module 21, high-concentration ozone water W2 is generated. The generated ozone water W2 is passed through the supply pipe L3, and then supplied to the chiller 31 in the subsequent stage. Drain water D2 of the dissolving membrane module 21 is passed through the waste water pipe L7 and then stored in the drain tank 5.

Note that heated ultrapure water (warm ultrapure water) is generally used to dissolve ozone gas at a high concentration for generation of high-concentration ozone water, so that the high-concentration ozone water W2 described above usually has a water temperature of 20° C. or more. In the semiconductor substrate cleaning apparatus 10, the supply pipe L2 may be provided with a heating device (not illustrated) for controlling the temperature of the degassed ultrapure water W1 to be supplied to the dissolving membrane module 21. The ozone water generating step may include a step of heating the degassed ultrapure water W1.

(Cooling Step)

Next, in a cooling step, the ozone water W2 supplied to the chiller 31 is cooled to 0° C. or more and less than 20° C. The ozone water W3 cooled to 0° C. or more and less than 20° C. is passed through the supply pipe L4 and then supplied to the cleaning tank 41 in the subsequent stage.

Note that the cooling step may be performed with a chiller unit having plural chillers 31 connected side by side by switching the operating states of the plural chillers 31 according to the degree of deterioration of the cooling function of each chiller 31. A chiller 31 to be used can be selected by switching the operating states of the plural chillers 31. Therefore, even when there is a chiller 31 whose cooling function deteriorates due to, for example, occurrence of microorganism or the like, the operation of the entire chiller unit can be continued without being stopped, so that the production efficiency of the cooled ozone water W3 is enhanced.

(Cleaning Step)

In a cleaning step, first, when the cooled ozone water W3 of a predetermined amount is supplied to the cleaning tank 41, a semiconductor substrate is transported into the cleaning tank 41 by transporting means (not illustrated). The semiconductor substrate transported into the cleaning tank 41 is immersed in the cooled ozone water W3 to be cleaned. When a predetermined time has elapsed, the cleaned semiconductor substrate is transported out of the cleaning tank 41 by the transporting means. Note that the transporting means may be configured to transport plural semiconductor substrates into and out of the cleaning tank 41. The ozone water W3 after the semiconductor substrate has been immersed and cleaned is passed through a waste water pipe (not illustrated) and then discharged to the outside of the cleaning tank 41. Then, the cleaning step is repeatedly performed on a semiconductor substrate to be cleaned next.

As described above, according to the cleaning method of the present invention, since the activity of dissolved ozone is reduced by using low-temperature ozone water which has been cooled to a predetermined temperature, particularly a temperature of 0° C. or more and less than 20° C., for the cleaning of the semiconductor substrate, formation of an oxide film on the surface of the substrate can be suppressed, so that it is possible to reduce the loss of the substrate material.

The present invention has been described above with reference to drawing. However, the present invention is not limited to the foregoing embodiment, and various changes may be implemented. In the present embodiment, the cleaning of the semiconductor substrate is performed by the immersion type using the cleaning tank 41 in the cleaning means 4. However, if it is possible to clean the semiconductor substrate with the ozone water W3 cooled to 0° C. or more and less than 20° C., the cleaning may be performed, for example, by the single wafer type for jetting the ozone water W3 to the semiconductor substrate.

### EXAMPLES

Hereinafter, the present invention will be described in more detail based on examples, but the present invention is not limited to the following examples.

A cleaning treatment on a semiconductor substrate was performed by using the cleaning apparatus 10 for the semiconductor substrate illustrated in FIG. 1. First, the semiconductor substrate was immersed in normal-temperature ozone water (15 ppm) for 5 minutes, and then immersed in 0.5 wt % dilute hydrofluoric acid for 5 minutes to clean the surface.

### Example 1

The cleaned semiconductor substrate was immersed in ozone water W3 cooled by the chiller 31 for 5 minutes to be cleaned, and then the thickness of the oxide film was measured by an ellipsometer.

### Comparative Example 1

After the immersion cleaning was performed on the cleaned semiconductor substrate in a manner similar to that of the Example 1 except that the ozone water for the immersion cleaning of the semiconductor substrate was not cooled, and the thickness of the oxide film was measured by the ellipsometer.

Table 1 illustrates numerical values of the thickness of the oxide film after the immersion cleaning using the ozone water for the Example 1 and the Comparative Example 1. As is apparent from this result, the activity of ozone in ozone water can be reduced by cooling the temperature of the ozone water for immersing the semiconductor substrate to 0° C. or more and less than 20° C., and the thickness of the oxide film can be controlled even by the same immersion time.

TABLE 1

| | | COMPARATIVE |
|---|---|---|
| | EXAMPLE 1 | EXAMPLE 1 |
| USED SUBSTRATE | Si (100) WAFER | Si (100) WAFER |
| ULTRAPURE WATER | 5 | 5 |
| FLOW RATE [L/min] | | |
| OZONE WATER | 15 | 15 |
| CONCENTRATION [ppm] | | |
| OZONE WATER | 12 | 26 |
| TEMPERATURE [° C.] | | |
| IMMERSION TIME [min] | 5 | 5 |
| THICKNESS OF OXIDE | 8.284 | 15.292 |
| FILM [Å] | | |

As described above, according to the cleaning apparatus and the cleaning method for a semiconductor substrate of the present invention, it is possible to clean and remove organic substances, such as resist, and metal foreign materials remaining on the surface of a substrate, and reduce the loss of substrate material in the cleaning step.

### INDUSTRIAL APPLICABILITY

The present invention is useful as a cleaning apparatus and a cleaning method for contaminants of organic substances, such as resists, and metal foreign materials generated in a manufacturing process in manufacturing of semiconductor devices.

### DESCRIPTION OF REFERENCE NUMERALS

10 cleaning apparatus for semiconductor substrate
1 degassing means
11 degassing membrane module
12 vacuum pump
2 ozone water generating means
21 dissolving membrane module
22 ozone generating device
3 cooling means
31 chiller
4 cleaning means
41 cleaning tank
5 drain tank
L1, L2, L3, L4 supply pipe
L5 vacuum pipe
L6, L7 waste water pipe
L8 oxygen gas supply pipe
L9 ozone gas supply pipe
W ultrapure water
W1 degassed ultrapure water
W2 ozone water
W3 cooled ozone water
D1, D2 drain water

1. A substrate cleaning apparatus for cleaning a substrate by using ozone water, comprising:
cooling means for cooling ozone water of 20° C. or more to a predetermined temperature; and
cleaning means for cleaning a substrate with ozone water cooled by the cooling means.

2. The substrate cleaning apparatus according to claim 1,
wherein the cleaning means includes a cleaning tank for cleaning the substrate by immersing the substrate in the ozone water cooled by the cooling means.

3. The substrate cleaning apparatus according to claim 1, wherein the cooling means includes a chiller capable of cooling ozone water to 0° C. or more and less than 20° C.

4. The substrate cleaning apparatus according to claim 1, further comprising ozone water generating means for generating ozone water to be supplied to the cooling means, wherein
the ozone water generating means includes an ozone generating device for generating ozone, and a dissolving membrane module for dissolving ozone generated by the ozone generating device in ultrapure water.

5. The substrate cleaning apparatus according to claim 4, further comprising degassing means for degassing ultrapure water to be supplied to the dissolving membrane module, wherein
the degassing means includes a degassing membrane module and a vacuum pump.

6. A substrate cleaning method for cleaning a substrate by using ozone water, comprising:
a cooling step of cooling ozone water of 20° C. or more to a predetermined temperature; and
a cleaning step of cleaning the substrate with the ozone water cooled in the cooling step.
